(19) United States
(12) Patent Application Publication
(10) Pub. No.: US 2012/0293964 A1
(43) Pub. Date: Nov. 22, 2012

(54) POWER ELECTRONIC MODULE WITH NON-LINEAR RESISTIVE FIELD GRADING AND METHOD FOR ITS MANUFACTURING

(75) Inventors: Felix GREUTER, Baden-Rutihof (CH); Jürgen SCHUDERER, Zurich (CH); Lise DONZEL, Wettingen (CH)

(73) Assignee: ABB TECHNOLOGY AG, Zurich (CH)

(21) Appl. No.: 13/526,078

(22) Filed: Jun. 18, 2012

Related U.S. Application Data
(63) Continuation of application No. PCT/EP2010/069904, filed on Dec. 16, 2010.

(30) Foreign Application Priority Data
Dec. 17, 2009 (EP) 09179630.0

(51) Int. Cl. H05K 7/06; H01L 21/56

(52) U.S. Cl. 361/728; 438/118; 257/E21.502

(57) ABSTRACT

Exemplary embodiments are directed to a power electronic device with an electronic device including a substrate, a metal layer formed on the substrate and a field grading means located along an edge of the metal layer. The field grading means has a non-linear electrical resistivity.

### RELATED APPLICATIONS

This application is a continuation under 35 U.S.C. §120 of International Application No. PCT/EP2010/069904 filed on Dec. 16, 2010, designating the U.S. and claiming priority to European application No. 09179630.0 filed in Europe on Dec. 17, 2009, the contents of which are hereby incorporated by reference in their entireties.

### FIELD

The disclosure relates to a power electronic module with a field grading and a method for producing such a power electronic device.

### BACKGROUND

In power electronic modules, electric field enhancements may occur at conductive components with a small radius of curvature as for example tips and edges of electrodes, semiconductors or metallic particles. Such electric field enhancements may lead to partial discharges and electrical breakdown, which lead to damage and failure of the power electronic module.

In order to avoid such field enhancements, that is, in order to grade the electric field, the geometries of the components can be changed, e.g., by rounding tips and edges, which is efficient, robust and reliable. In addition, this geometric field grading is not affected by the frequency of the voltage applied to the electronic device. However, it is not always possible to avoid sharp edges. In power electronic substrates for example, the application of Copper electrodes on ceramic substrates by bonding or brazing does not easily allow a 3D-bended geometry of the electrodes.

It is also known, that materials with selected electrical resistivity or high permittivity can be placed in the regions in which the electric field is to be graded. However, known field grading strategies provide either only small efficiency or exhibit unwanted side-effects as for example high leakage currents and frequency dependencies.

U.S. Pat. No. 6,310,401 discloses a high-voltage module with a high-impedance layer bridging top and bottom metallization of a metallic-ceramic substrate. As a result, a linear resistive field grading is achieved. This kind of field grading however, is limited mainly by the strong sensitivity to the specific choice of the resistivity value: It can only be applied for a narrow resistivity window in which the resistivity is low enough to provide some field grading and at the same time is high enough to keep leakage currents, and therefore losses, sufficiently small. Additionally, the linear resistive field grading is restricted by its frequency dependence, meaning that the penetration of the electric potential from the metallization end into the field grading layer, and in this way the effectiveness of the field grading depends on the frequency of the voltage signal. As an example, HV power electronic devices, such as IGBT modules, have to pass a partial discharge test at a frequency, for example, of 50 Hz, whereas frequency components up to several kHz are present during operation. In this way, field grading performance cannot be optimum for test and operational conditions at the same time.

US20010014413 discloses a substrate for a high-voltage modules with a high permittivity layer in contact to an electrode edge. In this way, a linear refractive field grading is achieved. This linear refractive field grading however, is mainly limited by the fact that high-permittivity materials often have high losses and low breakdown strength. There is another issue when using refractive field grading for common high-voltage power electronic substrates, which is that the permittivity of the field grading means has to be chosen particular high since usually a AlN ceramic is used which has already a quite high relative permittivity ε_{AlN}=8.5-10 and because the quality of refractive field grading is largely determined by the permittivity ratio ε_{layer}/ε_{substrate}.

### SUMMARY

An exemplary power electronic module is disclosed comprising: an electronic device including an insulating substrate for carrying semiconductor components; at least one metal layer formed on the substrate; and a field grading means located on the substrate along at least one edge formed between the at least one metal layer and the insulating substrate, wherein the field grading means has a non-linear electrical resistivity.

An exemplary method for producing an electronic device is disclosed comprising the steps of: mixing fillers with non-linear electrical resistivity and optional other fillers in an insulating matrix; and applying the filler/matrix compound as the encapsulation of the electronic device.

### DESCRIPTION OF THE DRAWINGS

The invention will be explained in more detail in the following description with reference to embodiments shown in the figures, in which:

FIG. 1 shows part of the cross section of a first electronic device with a field grading means of a power electronic module in accordance with an exemplary embodiment of the present disclosure;

FIG. 2 shows a characteristic resistivity-electric field strength-curve of the field grading means in accordance with an exemplary embodiment of the present disclosure;

FIG. 3 shows part of the cross section of a second electronic device with a field grading means of a power electronic module in accordance with an exemplary embodiment of the present disclosure;

FIG. 4 shows part of a power electronic module with the electronic device of FIG. 1 in accordance with an exemplary embodiment of the present disclosure; and

FIG. 5 shows part of the cross section of a third electronic device with a field grading means of a power electronic module in accordance with an exemplary embodiment of the present disclosure.

### DETAILED DESCRIPTION

Exemplary embodiments of the present disclosure provide a system for a power electronic module with improved field grading efficiency and with minimum leakage current and frequency dependencies.

An exemplary power electronic module according to the invention comprises an electronic device. The electronic device includes (e.g., comprises) an insulating substrate for carrying semiconductor components, at least one metal layer formed on the substrate and a field grading means located on the substrate along at least one edge formed between the at least one metal layer and the insulating substrate. The field grading means has a non-linear electrical resistivity.

An exemplary method for producing a power electronic module includes at least one metal layer is formed on a substrate, and a field grading means with nonlinear electrical resistivity arranged on at least one edge of at least one metal layer.

The field grading means can be made of a non-linear electrical material, i.e., of a material with non-linear electrical resistivity. The non-linear electrical material can be designed to have suitable switching field strength. The switching field strength is the electric field strength at which the material switches from insulating mode into conductive mode. On the one hand, this means the field grading means remains insulating during normal operation voltages of the electronic device and prevents undesired leakage currents. On the other hand, the field grading means becomes locally conductive during over-voltage conditions, e.g., during tests, and thereby efficiently reduces electric field enhancements that might otherwise lead to partial discharges and electrical breakdown. Consequently, efficient normal operation and the elimination of partial discharges and breakdown during over-voltages are reached with the nonlinear field grading means.

In the context of the present disclosure, “locally conductive” means conductive in an area, in which the electric field exceeds the switching field strength. Further, “locally conductive” means that between two electrodes which are in contact to the field grading means at most leakage current flows. This leakage current, which flows through the field grading means, should be at most of the order of the leakage current which flows through a semiconductor chip in his blocking state connected to the same electrodes.

Compared to linear resistive field grading, major benefits of using non-linear resistive field grading are (1) leakage currents occur only upon very high electric field strengths and not at operational conditions and (2) the frequency dependence of the field grading is considerably improved. This effect is outlined by referring to Rhyner et al., “One-dimensional model for nonlinear stress control in cable terminations”, IEEE Transactions on Dielectrics and Electrical Insulation, Vol. 4, No. 6, pp. 785-791, 1997. In this paper, a penetration length l is evaluated, which corresponds to the distance from the metallization end at which the electric potential within the field grading material is reduced to a fraction of l/e, where e is the Euler's number. It is found that

$$l \sim {ω}^{- \frac{1}{α + 1}} \cdot {U}_{0}^{\frac{α - 1}{α + 1}} \qquad ( 1 )$$

whereby ω is the angular frequency and α is the nonlinearity coefficient, defined by a nonlinear power law for the current density j according to

$$j = {j}_{c} \cdot {( \frac{E}{{E}_{c}} )}^{α} \qquad ( 2 )$$

with E_{c} being the critical switching field strength, and U₀ is the voltage amplitude. We can see now that for a linear resistive material with α=1, the penetration length is frequency dependent with l˜1/√f, i.e., the higher the frequency, the less the penetration. For the nonlinear resistive grading however with α>>1, the frequency dependence is negligible and the penetration can depend only on the applied voltage. In particular, leakage currents only occur when the penetration reaches levels of the insulation distance between the electrodes.

In other exemplary embodiments disclosed herein more than one metal layer can be arranged on the substrate and more than one edge can be covered by the same field grading means.

The current-voltage characteristics of the field grading means shows a nonlinearity coefficient larger than two, in particular larger than five and more preferably larger than ten in the region of the switching field strength. Thus, a sharp transition between insulating and conducting mode is reached at a well-defined switching field strength. Large nonlinearity coefficients reduce leakage currents and provide a penetration length that is not much affected by the frequency.

Exemplary embodiments of the present disclosure also provide that the switching field strength is larger than half of the ratio of the maximum critical test voltage of the electronic device and the length of the field grading means in the direction being parallel to the substrate surface and leading away from the edge.

According to another exemplary embodiment the field grading means includes an insulating high breakdown strength matrix and a filler material, in particular a microvaristor filler. A microvaristor filler is a granular material that exhibit varistor properties, i.e., non-linear electrical resistance. The non-linear filler can include ZnO and/or doped ZnO particles with a particle size of less than 100 μm, more preferably <50 μm, and most preferably <30 μm. Non-linear electrical resistive field grading is achieved by the non-linear filling material. In an exemplary embodiment, the field grading mean is arranged as a layer. However, it is also possible that an encapsulation of the substrate is the field grading means.

The insulating high breakdown strength matrix can include at least one further filler, wherein the filler is a semiconductor or a high permittivity material. According to another exemplary embodiment, that the at least one further filler has a reduced particle size compared to the microvaristor filler.

In an exemplary embodiment of the present disclosure, the semiconducting filling material is a powder of semiconducting filler material including SnO₂, SiC, doped SnO₂, carbon black or other forms of carbon and/or coated micro-mica particles in a specified size range, for example, from below 1 μm up to 10 μm. Free spaces between the non-linear particles, i.e. microvaristor-particles, can be filled with particles of the semiconducting filling material. Thus, field grading can be optimized even in free spaces between the non-linear particles, in particular in a vicinity of the metal edges, where large microvaristor particles may not reach close enough. Due to the semiconducting filler material, a resistive field grading can be achieved locally in addition to the non-linear resistive field. However, the amount of semiconductor filler has to be restricted such that the semiconductor filler remain under a threshold of percolation.

The field grading means can also or additionally further be filled up by a high-permittivity (=high-ε) material. The high-ε filling material can be a powder of high-ε filler material, such as TiO₂, BaTiO₃ or other Titanates, in the advantageous size range, for example, from below 1 μm up to 10 μm. The particles of the high-ε filling material may be used to fill free spaces between the non-linear particles. Field grading performance, in particular in the vicinity of the metal edges, can thus be enhanced locally even in free spaces between the non-linear particles. Due to the high-ε filler material, refractive field grading is achieved in addition to the non-linear resistive field grading.

Also, a mixture of semiconducting filler material and high-ε filler material may be used in the free spaces between the non-linear particles. In this case, an advantageous mixture of non-linear resistive field grading, resistive field grading and refractive field grading is achieved. Field grading performance is further enhanced.

Due to the small semiconductor filling material particles and to the small high-ε filling material particles, field grading may be achieved everywhere where it is needed; even in sharp and/or peaked edges and peaks.

According to an exemplary embodiment of the present disclosure, the field grading means is sealed against the environment with a passivation layer.

In an exemplary embodiment, the field grading means includes a matrix (e.g., a high strength insulating layer, e.g. polyimide and/or an electrically insulating gel or a hot melt or low melting glass) in which either the non-linear filling material or the non-linear filling material and the semiconducting filling material and/or the high-ε filling material are embedded.

The field grading means is advantageously realized by (1) mixing the microvaristor filler and/or the at least one further filler in a liquid polymer matrix, (2) applying the mixture on the substrate by needle-dispensing, printing, painting, coating or spraying and (3) curing the mixture by heat, Ultraviolet radiation or other means.

According to another exemplary embodiment, the microvaristor filler and/or the at least one further filler could be placed or pressed on the substrate. In this case, an adhesive can be applied first on the substrate in order to fix the fillers. Then, the insulating matrix is applied afterwards and infiltrates the filler-bed.

In another exemplary embodiment, the filler on the substrate can be sealed with a thin passivation film, in particular by a polymer such as Polyimide. This has the advantage that the microvaristor particles, e.g. ZnO-particles, are protected from environmental conditions that might affect their electrical characteristics. For example, in order to activate Copper surfaces, HV substrates can be exposed to reducing atmosphere during soldering of substrates onto the base plate of a module. The reducing atmosphere may give rise to chemical reactions with the filler particles, and in this way modify their electrical characteristics which may lead to reduced microvaristor capability. A glass layer might also be used as passivation.

In another exemplary embodiment of the present disclosure, the field grading means includes:
(1) a localized layer of semiconducting or high-ε fillers of particle size below 1 μm up to 10 μm right next the edge of electrodes; and
(2) a second layer of non-linear restive field grading layer covering said first layer.

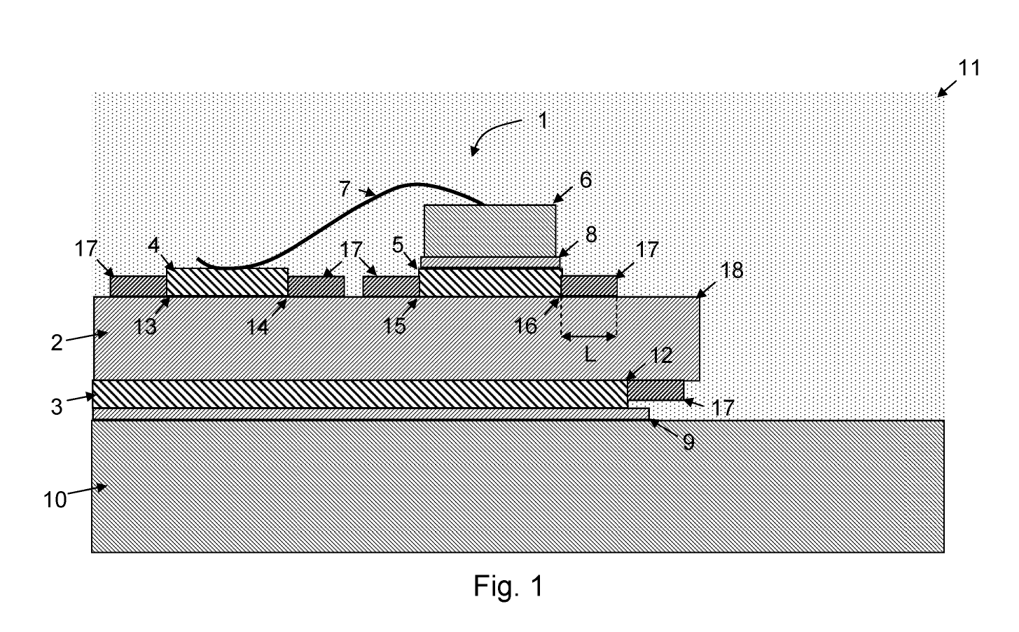

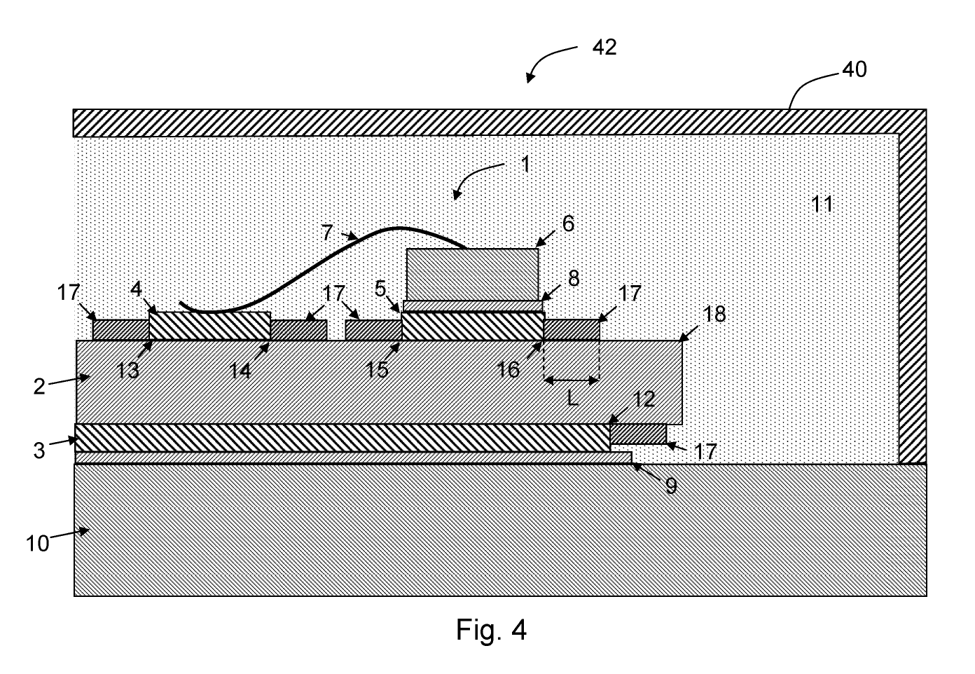

FIGS. 1 and 4 shows a cross-section of a part of an electronic device 1 as part of a power electronic module 42 according to a first embodiment of the invention. As shown in FIG. 4 only, the electronic device 1 is enclosed in a plastic casing 40 of the power electronic module 42.

FIG. 1 shows part of the cross section of a first electronic device with a field grading means of a power electronic module in accordance with an exemplary embodiment of the present disclosure. The electronic device 1 includes an insulating substrate 2, such as a ceramic substrate like aluminium nitride AlN, for example. The insulating substrate 2 can be sandwiched by a metal layer 3 on the first side of the insulating substrate 2 and a plurality of metal layers 4, 5 on the second side opposite of the first side. However, exemplary embodiments disclosed herein are not restricted by the number of metal layers 3, 4 and 5. An insulating substrate 2 with only one metal layer is also possible. Metal layers 3, 4 and 5 are normally realized in Copper (Cu). The metal layers 4 and 5 could be for example electrodes for semiconducting chips 6, bond wires 7, current load-carrying terminals, control terminals, conductor tracks or passive elements such as resistors. For example, the semiconductor chips 6 can be power semiconductors such as, for example, insulated gate bipolar transistors (IGBT) and diodes. Power electric modules as shown in FIG. 4 are based on the electronic device 1 with an IGBT as the semiconductor component 6. Such power electronic modules are commonly called IGBT modules. The semiconductor chip 6 can be fixed on the metal layer 5 by a soldering layer 8.

The electronic device 1 is normally bonded with the metal layer 3 on the first side via another solder layer 9 to a base plate 10, which is used as a heat sink. The electronic device 1 is encapsulated in a soft dielectric 11, which is usually Silicone gel. Instead of the encapsulation by the Silicone gel, encapsulation by another dielectric gel, inert gas or a dielectric liquid is also possible.

For high current capability, several such substrates 2 can be soldered on the same base plate 10 and connected in parallel. The plastic casing 40 surrounds all substrates including the soft dielectric 11 and only the terminals are accessible from outside.

The conducting metal layers 4 and 5 of the electronic device 1 as part of a power semiconductor module are normally operated at very high voltages, such as at least 100 V, more preferably of at least 800 V, and most preferably between 800 V and 8 kV. Therefore, strong electric field enhancements can be established, for example, at edges 12, 13, 14, 15, and 16 between the metal layers 3, 4 and 5 and the substrate 2, as at least one of the metal layers 4, 5 on the second side of the insulating ceramic 2 is on the very high voltage level and the metal layer 3 on the first side is grounded. This could lead to the ignition of partial discharges at these edges and consequently, to an electrical breakdown of the electronic device.

Therefore, the exemplary field grading means 17 according to the present disclosure, which has a non-linear electrical resistivity, can be arranged at the edges 12 to 16 to protect the electronic device 1 from partial discharges.

It is advantageous to cover the entire edge around each metal layer and the insulating substrate 2 by the field grading means 17. However, due to the geometric arrangement of the metal layers 3, 4, 5, semiconducting chips 6, bond wires 7, current load-carrying terminals, control terminals and/or passive elements to each other or other reasons could prevent the covering of the entire edge around each metal layer. It is however still advantageous to cover only a part of the edge around each or some metal layers. In particular it is advantageous to cover, for example, at least 50% of the length of the edges around the metal layers 3, 4, 5, more preferably 80% and most preferably 90% of the length of the edges around the metal layers 3, 4, 5.

The field grading means 17 according to an exemplary embodiment can be made of or at least includes a granular material with varistor properties. That is that the resistivity of the granular material of the field grading means 17 shows a non-linear resistivity behaviour as function of the electric field strength.

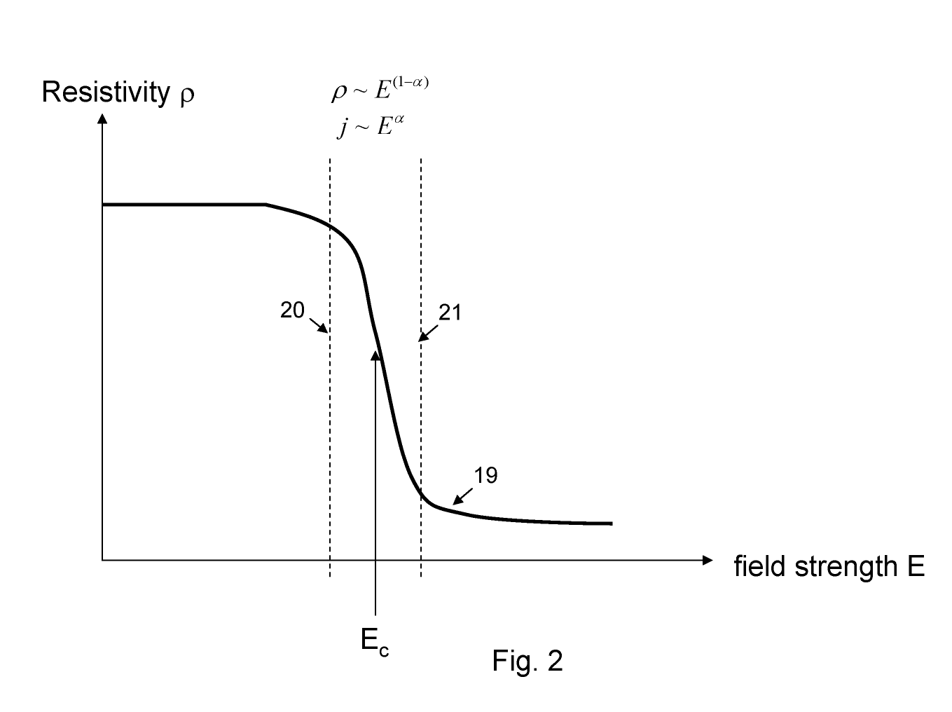

FIG. 2 shows a characteristic resistivity-electric field strength-curve of the field grading means in accordance with an exemplary embodiment of the present disclosure. In particular, FIG. 2 shows a characteristic resistivity-electric field strength-curve 19 of a material with varistor properties. A material with varistor properties can also be referred to as varistor type material. Such varistor type material remains insulating, i.e. shows high resistance, at low field strengths. The varistor type material further shows a transition at a switching field strength E_{c} and becomes conductive for electrical field strengths being higher than the switching field strength E_{c}. The switching field strength E_{c} is defined as the point where the resistivity is dramatically reduced. More precisely, the switching electric field strength E_{c} is the turning point of the characteristic resistivity-electric field strength-curve 19. The transition behaviour in the switching region shown in FIG. 2 between the dashed vertical lines 20 and 21 is characterised by ρ˜E^{(1-α)} and j˜E^{α} with the nonlinearity coefficient α, whereby ρ denotes the electrical resistivity, j the current density, and E the electric field strength. The varistor material shows more or less constant ohmic resistivity outside of the switching region.

The switching field strength E_{c} can be larger than 0.5×Uₘₐₓ/L, in particular larger than 0.8×Uₘₐₓ/L with Uₘₐₓ being the maximum voltage during a critical test with respect to partial discharges or electrical breakdown. The voltage Uₘₐₓ is also referred to as the maximum critical test voltage of the electronic device. The length L is shown in FIG. 1 and is the dimension of the field grading means 17 in the direction parallel to the surface of the substrate 2 and perpendicular to the edge. The said condition for E_{c} guarantees that a considerable part of the voltage drop occurs along the field grading means 17 and in this way provides an effective field grading. Thus, partial discharges and electrical breakdown are prevented. The relation can be understood by referring to equation (1), which shows that the penetration length l is linear dependent upon the voltage amplitude Uₘₐₓ for that case that α>>1.

As an example, the IEC 61287 insulation test procedure for 6.5 kV IGBT modules foresees a partial discharge testing at an AC peak voltage of Uₘₐₓ=5.1*√2=7.2 kV. The free border between the edge 16 of the metal layer 5 and an edge 18 of the insulating substrate 2 can be 2 mm. Thus, the length L is normally limited by 2 mm if applying the field grading means 17 on the metallization free border of the insulating substrate 2. Consequently, a field grading means with a switching field strength of above 1.8 kV/mm (=0.5×Umax/L) would be suitable to grade the electric field along the metallization free border of the insulating substrate 2.

For the field grading means 17, according to the first embodiment of the invention, a material is chosen with a nonlinearity coefficient a larger than 2, for example, in particular larger than 5 and more preferably larger than 10. The larger the nonlinearity coefficient α is, the smaller the switching range of the material becomes. Thus, the characteristic field strength-curve 19 approaches to a step function and the switching field strength E_{C} becomes well defined. Large nonlinearity coefficients a also reduce leakage currents and provide a penetration length that is not much affected by frequency.

The frequency independence is of importance since it guarantees the transferability of test results, usually performed at 50 Hz, to the much higher frequency components, to which power electronic modules are exposed to in operation.

The field grading means 17 according to an exemplary embodiment includes an insulating matrix in which the granular material with varistor properties is embedded as a filler. Such filler is also referred to as a microvaristor filler. The microvaristor filler can be granular doped zinc oxide (ZnO). Such ZnO has a high non-linearity coefficient and the electric characteristics, like the switching field strength of ZnO, can be widely tailored by specified doping and processing. However, other particles like doped tin dioxide (SnO2) or silicon carbide (SiC) or carbon black might be used as varistor filler for the field grading means 17 as well.

The microvaristor filler made of, for example, doped polycrystalline ZnO can be based on particles with a granulation size, i.e., diameters, of less than 100 μm, more preferably less than 50 μm, and most preferably less than 30 μm. Small granulation size is specified since in this way particles can come closer to the critical edges 12 to 16 of the electronic device 1 in order to grade the electric field at these edges 12 to 16.

In another exemplary embodiment, the problem that the electric field should be graded as close to the edges 12 to 16 as possible, can also be resolved by adding additional fillers to the matrix with field grading performance. Micron or sub-micron scale particles exist for refractive or linearly resistive field grading. BaTiO₃ is an example for a high-permittivity (high-□ε) filler material for refractive field grading and semiconductor fillers like SnO₂ or carbon black or coated micro-mica can be used for linear resistive field grading. The mixture of microvaristor filler and smaller-sized semiconductor and/or high-ε fillers/filler can prevent partial discharges in the vicinity of the edges 12 to 16. An advantageous size range of the additional fillers, for example, from below 1 μm up to 10 μm is used. Attention has to be drawn to the amount of semiconductor filler. The semiconductor filler should remain under the percolation threshold. Otherwise, the semiconductor filler bridges the microvaristor particles and bypasses the non-linear resistance-effect of the microvaristor particles.

High-permittivity means a relative permittivity which is higher than the one of the insulating varistor matrix, and preferably also higher that the one of the insulating substrate, in particular a relative permittivity which is higher than 10.

FIGS. 1 and 4 shows exemplary field grading means 17 having a length L. The shape of the field grading means 17 are not restricted to the shown geometry. The length L should be large to prevent partial discharge or electrical breakdown at the end of the field grading means 17 (whereby “end” is a position x=L, with x denoting the distance from the metallisation edge along the field grading means).

As shown in FIG. 1, more than one field grading means 17 can be arranged at the edges 12 to 16. As shown, the field grading means 17 on the second side of the substrate 2, which are arranged at the edges 13 to 16 to the metal layers 4, 5, are not in contact with the grounded metal layer 3 on the first side of the substrate 2. In general, at least one of the field grading means 17 is not grounded.

Further, it should be noted, that it is possible to arrange field grading means only along the edges of some of the metal layers.

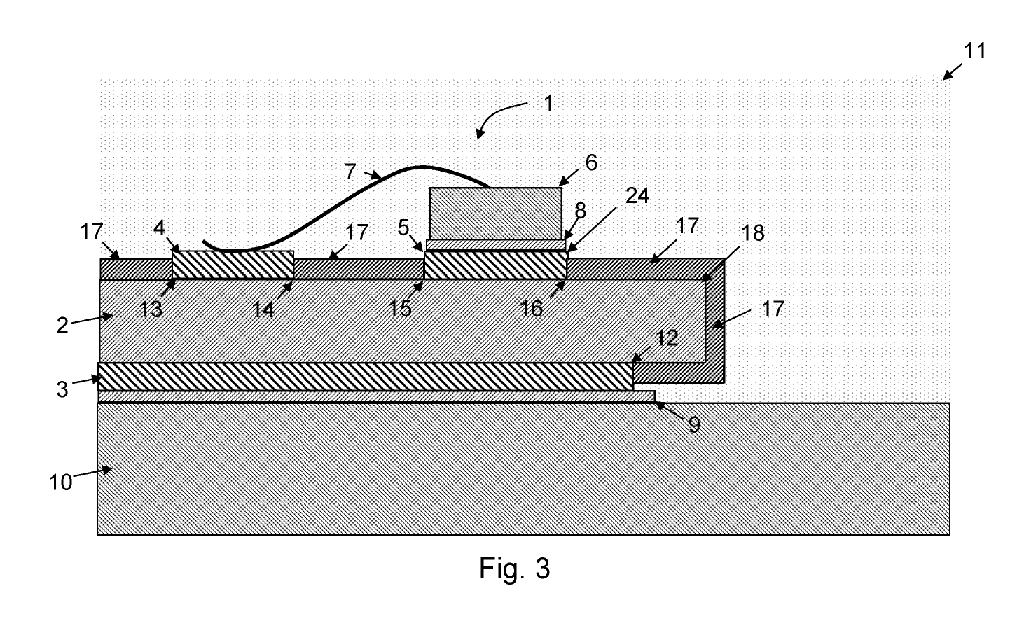

FIG. 3 shows part of the cross section of a second electronic device with a field grading means of a power electronic module in accordance with an exemplary embodiment of the present disclosure. This electronic device according to FIG. 3 can be used in a similar way as the electronic device according to FIG. 1 in an exemplary power semiconductor module according to the present disclosure. For the sake of brevity, means of the second and further embodiments being equal to means of the first embodiment show the same reference numbers and their repetitive description is omitted.

The field grading means 17 according to the second embodiment is located between two metal layers 4 and 5 on the substrate 2. This field grading means 17 contacts the metal layer 4 as well as the metal layer 5. The field grading means 17 is located along the edge 14 of the metal layer 4 as well as along the edge 15 of the metal layer 5. This has the advantage that only one layer of the field grading means 17 is needed for two edges 14 and 15. In addition, edges between the substrate 2 and the field grading means as in the first embodiment of the invention are prevented. The field grading means 17 further encloses one side surface of the substrate 2 connecting the first side and the second side of the substrate 2 from the edge 16 of the metal layer 5 being closest to the side surface of the substrate 2 on the second side up to the edge 12 of the metal layer 3 on the first side of the substrate 2. Thus, all the edges of the substrate 2 are covered by the field grading means 17. Consequently, high field strengths and possible discharges at the edges of the substrate 2 are prevented. In addition, the length of the field grading means 17 is increased such that materials with lower switching electric field strengths can be used.

In another exemplary embodiment the field grading means can include a combination of the embodiment shown in FIG. 1 and the embodiment shown in FIG. 3. As in the embodiment shown in FIG. 1 the metal layers 4, 5 on the second side are not necessarily connected to each other by the field grading means 17. In other words, more than one field grading means 17 can be provided on the second side of the substrate 2. As in the embodiment shown in FIG. 3, the field grading means 17 further encloses one side surface of the substrate 2 connecting the first side and the second side of the substrate 2 from the edge 16 of the metal layer 5 being closest to the side surface of the substrate 2 on the second side up to the edge 12 of the metal layer 3 on the first side of the substrate 2.

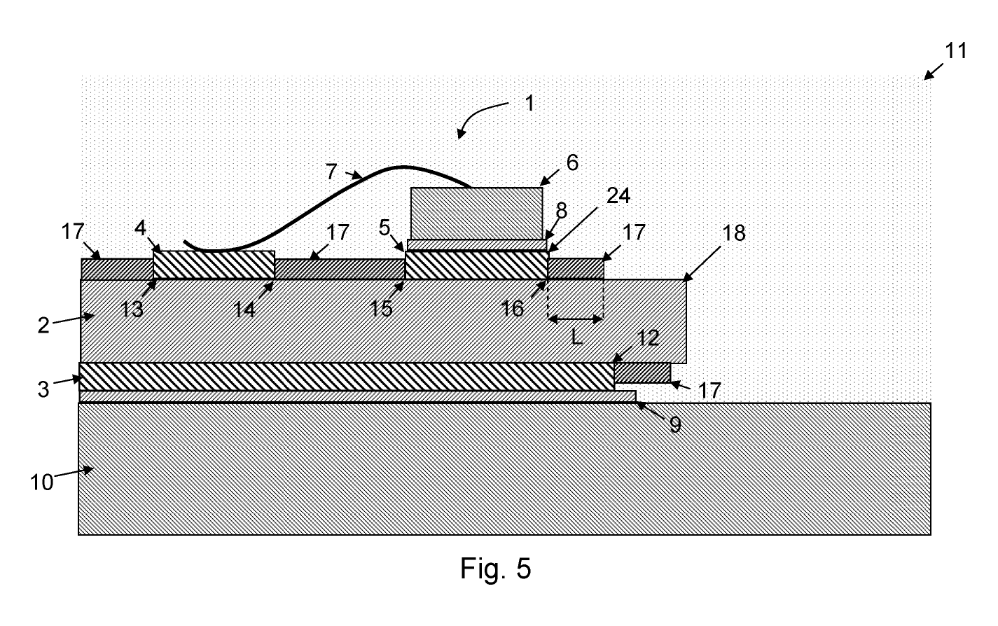

FIG. 5 shows part of the cross section of a third electronic device with a field grading means of a power electronic module in accordance with an exemplary embodiment of the present disclosure. As shown in FIG. 5, the field grading means 17 according to the third embodiment is located between two metal layers 4 and 5 on the substrate 2. This field grading means 17 contacts the metal layer 4 as well as the metal layer 5 in a similar way as in the second embodiment shown in FIG. 3. The field grading means 17 is located along the edge 14 of the metal layer 4 as well as along the edge 15 of the metal layer 5. This has the advantage that only one layer of the field grading means 17 is needed for two edges 14 and 15. In addition, edges between the substrate 2 and the field grading means as in the first embodiment of the invention are partly prevented.

In an exemplary embodiment of the present disclosure, one field grading means encapsulates all metal layers 4, 5 and 3 on both sides of the substrate 2. Consequently, the edges like 24 of the metal layers 4 and 5 creating high electric field strengths and even edges of the semiconductor chips 6 are covered by the field grading means and the probability of partial discharges at these locations is reduced.

In another exemplary embodiment, the microvaristor filler can also be mixed into the encapsulating soft dielectric 11 instead of an extra layer as shown in the first and second embodiment. Thus, in this embodiment the field grading means is formed by the soft dielectric which shows a non-linear resistivity.

The exemplary first and second electronic devices 1 according to exemplary embodiments of the present disclosure can be produced in a first step by bonding the metal layers 3, 4 and 5 on the substrate 2. This can be done for example by the techniques of active metal brazing or direct copper bonding.

In a second step, the field grading means 17 can be applied on the substrate 2. There are several techniques to produce, realise and apply the field grading means 17. In a first example, the microvaristor filler is mixed in the liquid base components of the matrix, e.g., the base components of a Polyimide. The mixture can then be applied by a needle-dispensing process on the substrate 2 along the edges 12 to 16 and finally cured by heat, UV radiation or other means. Alternatively, the mixture can also be printed, painted, coated or sprayed along the edges 12 to 16 and cured in a second step. This applies also for mixtures of matrix with different sized fillers.

In another exemplary embodiment, the substrate can be prepared with an adhesive or binder in a first step and the microvaristor filler and possibly additional fillers can be mixed among each other and directly placed along the edges 12 to 16 in a second step.

If the microvaristor particles, i.e., the layer of microvaristor particles, are not fully embedded by a polymer matrix, the particles can be sealed with a thin passivation layer, for example by a polymer film in a third step. If microvaristor particles are not sealed, then they can react with the environment, in particular with the reducing atmosphere applied during soldering of substrates on the base plate 10. This chemical reaction can change the electrical characteristics of the microvaristor particles and thereby reduce their capability for field grading. A possible polymer for the passivation layer is Polyimide. Also non-polymeric sealing layers are possible, such as glass.

As already discussed, the field grading means 17 can be realized as a layer or as an encapsulation, i.e., by adding the fillers into the encapsulation material 11. Alternative encapsulations to Silicone gel are other dielectric gels or dielectric liquids or inert gas.

The invention has been described in detail with particular reference to preferred embodiments thereof and examples, but it will be understood that variations and modifications can be effected within the spirit and scope of the invention covered by the claims which may allow different types of field grading means.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.
1 electronic device
2 insulating substrate
3, 4, 5 metal layers
6 chip
7 wire
8 soldering layer
9 another solder layer
10 base plate
11 soft dielectric
12-16 edge
17 field grading means
18 edge
19 field strength-curve
24 edge
40 plastic casing
42 power electronic module
E_{C} switching field strength
20, 21 vertical line
ρ electrical resistivity
E electric field strength
α nonlinearity coefficient
j current density
Uₘₐₓ maximum voltage during a critical test
L dimension of the field grading means 17
ε permittivity

What is claimed is:

1. A power electronic module comprising:
an electronic device including an insulating substrate for carrying semiconductor components;
at least one metal layer formed on the substrate; and
a field grading means located on the substrate along at least one edge formed between the at least one metal layer and the insulating substrate, wherein the field grading means has a non-linear electrical resistivity.

2. The power electronic module according to claim 1, wherein a characteristic current density—electric field strength—curve of the field grading means shows a nonlinearity-coefficient larger than two at a switching field strength.

3. The power electronic module according to claim 2, wherein the nonlinearity-coefficient is larger than five at a switching field strength.

4. The power electronic module according to claim 2, wherein the nonlinearity-coefficient is larger than ten at a switching field strength.

5. The power electronic module according to claim 2, wherein the switching field strength is larger than half of the ratio of a maximum critical test voltage of the electronic device and a length of the field grading means in a direction of the substrate surface.

6. The power electronic module according to claim 1, wherein the electronic device comprises more than one metal layer operated at very high voltages of at least 800V.

7. The power electronic module according to claim 1, wherein the electronic device comprises more than one metal layer operated at very high voltages of up to 8 kV.

8. The power electronic module according to claim 1, wherein the field grading means is not grounded.

9. The power electronic module according to claim 1, wherein the field grading means is located along at least 50% of a length of the edge around at least one of the metal layer,

10. The power electronic module according to claim 9, wherein the field grading means is located along at least 80% of the length of the edge.

11. The power electronic module according to claim 9, wherein the field grading means is located along at least 90% of the length of the edge.

12. The power electronic module according to claim 9, wherein the field grading means is located along at least 50% of the length of the edge around all the metal layers on at least one side of the substrate.

13. The power electronic module according to claim 12, wherein the field grading means is located along at least 80% of the length of the edge around all the metal layers on at least one side of the substrate.

14. The power electronic module according to claim 12, wherein the field grading means is located along at least 90%, of the length of the edge around all the metal layers on at least one side of the substrate.

15. The power electronic module according to claim 1, wherein at least two metal layers are formed on the substrate and the field grading means is located on the substrate along at least one edge of each of the at least two metal layers.

16. The power electronic module according to claim 1, wherein the field grading means comprises an insulating matrix filled with particles having non-linear electrical resistivity.

17. The power electronic module according to claim 16, wherein the insulating matrix comprises at least one further filler, wherein the filler is a semiconductor or a high permittivity material.

18. The power electronic module according to claim 17, wherein the at least one further filler has a reduced particle size compared to filler with non-linear electrical resistivity.

19. The power electronic module according to claim 1, wherein the field grading means is composed of particles having non-linear electrical resistivity, which are bonded on the substrate.

20. The power electronic module according to claim 16, wherein the non-linear resistive particles of the field grading means are granular microvaristors made of doped polycrystalline zinc oxide.

21. The power electronic module according to claim 1, wherein the field grading means is sealed with a passivation layer.

22. The power electronic module according to claim 1, wherein the power electronic module is an IGBT module.

23. A method for producing a power electronic module according to claim 1, comprising the steps of:
forming at least one metal layer on a insulating substrate; and
arranging a field grading means with non-linear electrical resistivity on at least one of the edges of the metal layers.

24. The method according to claim 23, comprising:
mixing fillers with non-linear electrical resistivity and optional other fillers in an insulating matrix;
one of needle-dispensing, printing, painting, coating, or spraying the mixture on the substrate; and
curing the mixture by heat or ultraviolet radiation.

25. The method according to claim 23, comprising:
applying an adhesive or binder on the substrate; and
placing or pressing a filler with non-linear electrical resistivity and optional other fillers on the substrate.

26. The method according to claims 23 comprising:
sealing the filler with a passivation layer.

27. A method for producing an electronic device comprising the steps of:
mixing fillers with non-linear electrical resistivity and optional other fillers in an insulating matrix; and
applying the filler/matrix compound as the encapsulation of the electronic device.
